(19) United States
(12) Patent Application Publication
(10) Pub. No.: US 2010/0231297 A1
(43) Pub. Date: Sep. 16, 2010

(54) ELECTRONIC DEVICE FOR SELF OSCILLATING CLASS D SYSTEM

(75) Inventor: Pieter Buitendijk, Nijmegen (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/377,618

(22) PCT Filed: Aug. 10, 2007
(86) PCT No.: PCT/IB07/53191

§ 371 Date: Feb. 16, 2009

(30) Foreign Application Priority Data
Aug. 15, 2006 (EP) 06118931.2
Aug. 10, 2007 (IB) PCT/IB2007/053191

(51) Int. Cl. H03F 3/217

(52) U.S. Cl. 330/251

(57) ABSTRACT

The present invention relates to an electronic device that includes an integrated power comparator circuit (1) for a self-oscillating class D system (100). The integrated power comparator circuit (1) has a modulation stage (10), wherein the modulation stage (10) comprises a compensation circuit (40) for providing a compensation signal to the modulation stage, which is dimensioned for compensating a variation of a process parameter for smoothing initialization of the self-oscillating class D system (100).

### FIELD OF THE INVENTION

The present invention relates to an electronic device for a self-oscillating class D system, more specifically to an electronic device for improved start up of a self-oscillating class D system.

### BACKGROUND OF THE INVENTION

It is generally known in the art that class D amplifiers are useful for providing high output currents in order to drive loads as for example in audio applications. The class D systems convert audio signals into a sequence of high frequency pulses, wherein the output of a power output stage is a square wave with a duty cycle in accordance with an audio input signal. Some self-oscillating class D systems use pulse width modulators (PWM) in order to provide a sequence of pulses that varies in accordance with the audio signal's amplitude. The pulses switch the power output transistors at a specific frequency. Some self-oscillating class D systems use other kinds of modulation, such as density modulation or the like. The output of a class D system is usually applied to a low pass filter in order to convert the pulses back into an amplified audio signal that drives one or more audio speakers. In order to convey the continuous audio input signal into a modulated sequence of pulses, a some class-D systems provides a self-oscillating loop including a comparator. It is a crucial point of self-oscillating class D systems to enter in a stable self-oscillating operation condition during start-up of the system. As the components, like the comparator or the passive components in the loop filter have inevitable production spread (as for example process variations for integrated circuits), there might be a start-up condition that can prevent the system from starting proper operation. For example, the comparator may suffer from an asymmetry resulting in a DC offset of its input signals. Under these circumstances, it is generally unpredictable, when the system will start oscillating for different starting conditions.

The typical self-oscillating class D systems usually comprise an output stage with two n type MOSFET transistors, which are driven by a respective high side driver and a low side driver. As only NMOS transistors are used, one NMOS transistor is coupled to the positive supply voltage. In order to activate the high side MOSFET, a high side driver is necessary that provides a considerably high gate voltage to the high side MOSFET. In particular, the gate voltage of the high side MOSFET must be higher than the positive supply voltage Vdd on the drain of the high side MOSFET. Such a high positive driver voltage is provided by coupling a bootstrap capacitor between the output of the power output stage (consisting of the two NMOS output transistors) and the high side driver (i.e. the gate of the high side MOSFET). Further, an additional voltage source charges the boot capacitor via a diode, if the output of the power output stage is on ground potential Vss. If subsequently, the output node of the power stage is switched to the positive supply voltage level Vdd, the first side of the bootstrap capacitor, due to the charge on the bootstrap capacitor, will be raised to a voltage level above the positive supply voltage level Vdd. Additionally, the conventional solutions usually provide a protection mechanism that prevents the class D amplifier from entering into normal operation, if the voltage on the bootstrap capacitor is too small. Accordingly, the high side transistor is disabled. Further, if the comparator has a DC offset level due to process variations, the output signal of the comparator indicates to activate the high side transistor, which is not allowed due to insufficient voltage on the bootstrap capacitor. So, the self-oscillating class D system according to the prior art will remain locked and unable to start.

There are several known concepts which aim to overcome the mentioned start-up problems. According to a first principle, a specific charge current is provided in order to precharge the bootstrap capacitor to a specific level before the power stage is enabled. However, this principle cannot be applied to supply voltages below 20 V. Further, this conventional mechanism will fail if an error situation occurs, after which the system needs a quick restart, i.e. within e.g. 100 msec. Accordingly, this conventional solution is not suitable for low supply voltages and systems needing quick recovery.

According to another conventional principle for avoiding hang up during the start-up procedure, the control logic for the output power stage is forced for a certain period of time to a logic LOW level (i.e. to ground or Vss), such that the output of the power output stage is forced to Vss. For this purpose, additional logical gates and a specific signal having a short pulse are provided. A drawback of this conventional method is the critical timing of the LOW period. The LOW pulse should be in good correlation with the oscillating frequency of the class D system. However, the pulse signal used to force the output to LOW level is defined on the integrated circuit comprising the power stage and the respective control logic, whereas the oscillating frequency is flexibly defined by the components of the loop. If the timing of the LOW period and the oscillating frequency are uncorrelated, this will typically result in undesired acoustic effects at the output of the class D amplifier.

### SUMMARY OF THE INVENTION

It is an object of the present invention to provide an electronic device that enables quick, reliable and smooth start-up of a self-oscillating class D systems even for low supply voltages.

The object is solved by the subject-matter of the independent claim 1. Accordingly, an electronic device is provided that includes an integrated power comparator circuit for a self-oscillating class D system. The integrated power comparator circuit includes a modulation stage, and the modulation stage includes an offset compensation circuit for compensating an offset of the modulation stage for smoothing initialization of the self-oscillating class D system. The compensation signal is adapted and dimensioned for compensating or slightly over-compensating the effect of a variation of a process or production parameter. Generally, process variations influence the electrical properties of the circuitry and the electronic components. In particular, if two components are supposed to have the same electrical properties, i.e. they should match, process variations can impair the functionality of the circuitry severely. Accordingly, if for example an offset due to process variations in the modulation stage sets the modulation stage in a particular initial state when the system is turned on, the present invention provides circuitry to compensate the offset that is due to a deviation of a process parameter. Other effects may be additional or reduced delays, noise, or the like. Compensating in this context can imply over-compensating in order to change the initial state.

As initialization of self-oscillating class D systems is often impaired by parameter variations of the modulation stage, which let the modulation stage stick to a particular value, the present invention provides an offset compensation circuit to overcome these problems. The conventional solutions suggest for example to introduce additional digital signals by means of combinatorial logic in order to impose digital levels of the output signals of the modulation stage. However, the present invention suggest to intervene at an earlier stage of processing. Instead of modifying the logic values of the signals which are already the result of process parameter variations, the present invention suggests to compensate the deviations closer to their point of origin. This approach provides a smoother initialization process than according to the prior art. Correlation between the self-oscillating frequency of the class D system and the compensation signal is less critical. A compensation signal according to the present invention is therefore dimensioned and adapted to compensate a specific effect of a parameter spread during production. This relates to all kinds of process characteristics which have an impact on the electrical characteristics of the components of the modulation stage. As parameters vary according to statistical distributions, the parameter variation is predictable within a specific range. The compensation signal is to be dimensioned such that the maximum deviation of a particular probability can be compensated or slightly over-compensated.

According to an aspect of the invention the modulation stage includes a comparator, and the offset compensation circuit provides an offset compensation signal for compensating an offset of the comparator. One effect of process variations during manufacturing is an undesired offset of the electronic components, such an offset of a comparator, or the differential pair of a comparator, etc. The present invention suggests to compensate these offsets by voltages or currents being applied to the components. Accordingly, the offset is compensated closer to its point of origin and the start-up procedure can be smoother than in prior art systems.

According to an aspect of the present invention the compensation signal introduces an unbalance into the comparator for compensating the offset of the comparator by introducing an additional current into an input stage of the comparator. This aspect of the invention relates to a specific configuration that is simple to implement and effective. Accordingly, a small current is introduced in a branch of the comparator. Due to an offset that is a result of process deviations, the comparator usually tends to have a specific initial stage, i.e. HIGH or LOW at the output, although the input signal may be different. The comparator remains in this state until the input signal changes substantially. In order to impose a different input state, a small current is introduced in a specific electrical path of the comparator such that the comparator is forced to switch to another state. As a result, the initial state of the comparator can be changed and hang-up of the self-oscillating system in the start-up phase is avoided.

According to still another aspect of the invention, the compensation signal provides a short pulse, such that the variation of the process parameter is compensated or slightly over-compensated for the duration of the pulse. The compensation as explained above may be carried out for only a very short period of time. Accordingly, only a short pulse is applied to the part of the modulation stage that is to be compensated. The pulse may be only a single-shot or a sequence of short pulses. They are typically much shorter than the period of the self-oscillating frequency of the self-oscillating class D system. The component or the circuit of the modulation stage to be compensated is forced to a different state only for this short period which is just long enough to provide suitable start-up conditions for the loop of the class D system.

According to still another aspect of the invention, the power output stage of the electronic device includes a first MOS transistor (MOSFET) and a second MOS transistor (MOSFET), which are driven by a respective first low-side driver and a second high-side driver, wherein the comparator is coupled to the low-side and the high-side driver. The MOS transistors are preferably both of the NMOS type. However, the present invention is not restricted to one specific type of transistor. If two NMOS transistors are used in the power output stage, there is usually a bootstrap capacitor coupled between the output node of the output power stage and the high side driver. In this configuration, problems can occur typically during start-up of the class D system as described above. Therefore, the present invention is particularly advantageous for systems including NMOS power output stages.

The present invention also suggests to apply at least one well defined DC offset to the modulation stage. During the start-up procedure, a small unbalance is introduced into the comparator in order to set the comparator's output to low. Consequently, the output of the power stage is also tied to LOW level during the start-up procedure. This mechanism provides enough time to have the boot capacitor charged to a sufficiently higher voltage level. The unbalance by a predefined DC offset of the comparator is only applied during a very short period of time, as for example during 1 μsec. The signal applied to the comparator is derived from a dedicated logical circuitry providing a time period of a sufficiently short value. The offset which is externally applied to the comparator is determined based on the maximum DC offset caused by process parameter variations. The general behavior of the comparator remains unchanged, except that the first switching cycle of the output power stage is forced to LOW level. The natural frequency of the self-oscillating class D system is not affected by the principle according to the present invention. Even during the first cycles when the loop starts switching, the natural frequency will be preserved avoiding additional disturbances of the duty cycles. Further, the principle according to the present invention provides a smooth start-up behavior without undesired audible effects. It should also be noticed, that the electronic device according to present invention, or parts of the electronic device, are preferably implemented as integrated circuits.

The object of the present invention is further solved by a method of designing an electronic device. The method includes the steps of providing a compensation circuit for a modulation stage of an integrated power comparator circuit for a self-oscillating class D system. According to this aspect of the invention, the compensation circuit is also adapted to provide a compensation signal to the modulation stage, wherein the compensation signal is dimensioned for compensating an effect of a variation of a production parameter for smoothing initialization of the self-oscillating class D system.

Still further, the object of the present invention is solved by a method of operating a class D system. The method includes the steps of providing a compensation signal to a modulation stage for an integrated power comparator circuit for a self-oscillating class D system, wherein the compensation signal is dimensioned for compensating an effect of a variation of a production parameter for smoothing initialization of the self-oscillating class D system. Preferably, the modulation stage has a comparator, and the offset compensation signal provides a pulse for compensating or over-compensating an offset of the comparator being the effect of the variation of the production parameter.

### BRIEF DESCRIPTION OF THE DRAWINGS

These and other aspects of the invention will be apparent from and elucidated with reference to the embodiment(s) described hereinafter. In the following drawings:

FIG. 1 shows a simplified block diagram of a self-oscillating class D system according to a first embodiment of the prior art,

FIG. 2 shows a simplified block diagram of a self-oscillating class D system according to a second embodiment of the prior art,

FIG. 3 shows a simplified block diagram of a self-oscillating class D system according to a third embodiment of the prior art,

FIG. 4 shows a simplified block diagram of a self-oscillating class D system according to an embodiment of the present invention,

FIG. 5 shows a simplified schematic of a comparator according to the present invention, and

FIG. 6 shows a simplified schematic of a circuit according to the present invention.

### DETAILED DESCRIPTION OF THE EMBODIMENTS

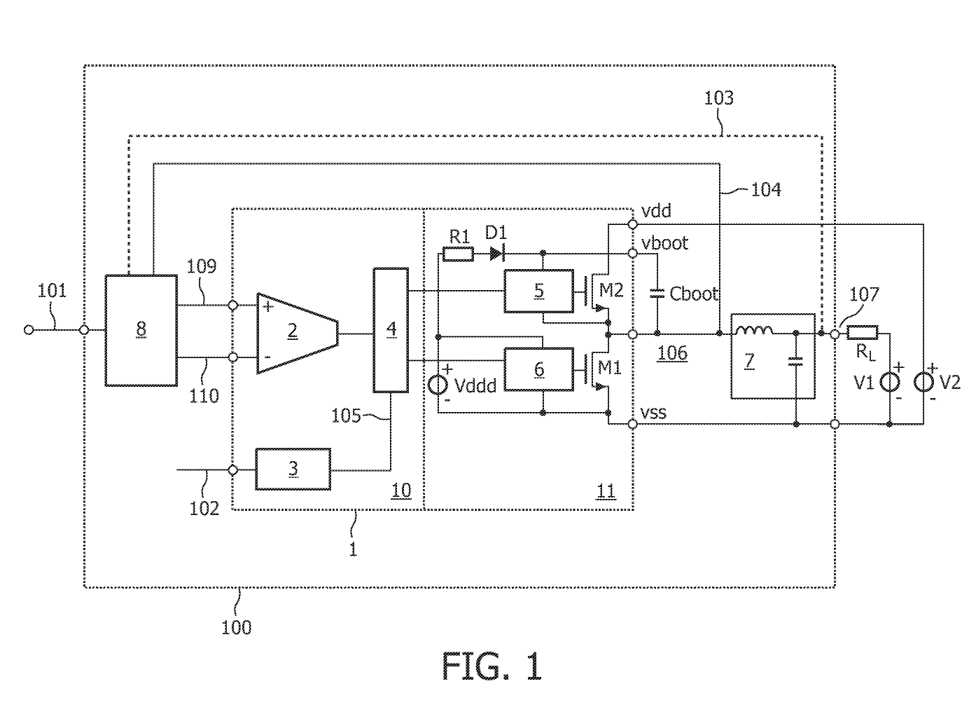

FIG. 1 shows a simplified block diagram of a self-oscillating class D system according to a first embodiment of the prior art. The self-oscillating class D system 100 includes an integrated circuit usually designated as an integrated power comparator 1.

The integrated power comparator 1 has substantially the same behavior as a comparator, except that the output signal 106 of the integrated power comparator 1 is modulated and rapidly switched between Vdd and Vss (ground) in accordance with an audio input signal 101. The supply voltage Vdd is provided by voltage source V2. The rapid switching between supply lines Vdd and Vss enables the integrated power comparator 1 to provide a current of several amperes on the output pin 106. The output signal on node 106 is typically modulated by pulse width modulation (PWM).

The self-oscillating class D system 100 of FIG. 1 is configured as a closed loop. Therefore, the class D system 100 further includes a discrete loop filter 8 as shown in FIG. 1. The loop filter 8 usually consists of passive components which provide one or more time constants in order to establish an overall transfer function of the loop. The loop is closed by either a feedback line 104 from the output pin 106, or alternatively by feedback path 103 from pin 107. Both feedback paths 103, 104 provide feedback to the loop filter 8. The loop has a typical oscillating frequency in the range of 200 kHz to 500 kHz.

An input signal 101 is applied to an input of the loop filter 8. Typically, the input signal is an audio signal. If no input signal 101 is present at the input of the loop filter 8, the output signal 106 is a square wave with a duty cycle of 50%. If the input signal 101 varies, the output signal, i.e. the pulse width of the output signal 106, is modulated in accordance with the input signal 101. Applying an input signal (typically an audio signal) to the input pin 101 of the loop filter 8 causes a modulation of the output signal 106. This results in a varying duty cycle of the output signal 106.

A low pass filter 7 is coupled to the output pin 106 in order to suppress high frequency components of the oscillating signal. The low pass filter 7 is dedicated to reconstruct the original input signal 101 at output node 107. The characteristics of the loop filter 8, the low pass filter 7 and the closed loop are not relevant for the present invention. The load resistor R_{L} is biased by voltage supply V1 at a DC level of half the supply voltage Vdd. In this situation, the average current in the load resistor R_{L} is zero. Typically, the voltage supply V1 charges an electrolytic capacitor (not shown) to Vdd/2 to maintain a smooth and constant voltage.

The integrated power comparator includes a modulation stage 10 and a power output stage 11. The modulation stage 10 includes a comparator 2, a mode logic 3, a control logic 4. The output signals 108, 110 of the discrete loop filter 8 are coupled to the comparator 2. The output of comparator 2 is a digital signal that is passed to control logic 4. Control logic 4 provides appropriate signals for driving the power output stage 11.

The power output stage 11 includes two drivers 5, 6 and two power MOSFETs. The high side driver 5 drives MOSFET M2, and the low side driver 6 drives MOSFET M1. The mode logic 3 provides a mode input pin for receiving a mode input signal 102 and providing an enable signal 105 for the control logic 4. The two MOSFETs M1 and M2 are both of the same type, i.e. they are NMOS transistors. Using a complementary output stage with an NMOS and a PMOS transistor would require substantially more area on an integrated circuit. Accordingly, the two MOSFETS are designed as NMOS transistors, only. The gate of the low side power MOSFET M1 is driven by the low side driver being supplied from an on-chip voltage source Vddd (e.g. Vddd may be 12 V). As the output pin 106 must raise to the supply voltage level Vdd, the gate of M2 must be raised up to approx. 12 V above the Vdd potential. Since such a high positive voltage is usually not available, a bootstrap capacitor Cboot is used to supply the high side driver 5 as a floating voltage source. The bootstrap capacitor is coupled between the output node 106 and a pin denoted vboot (usually provided as an external pin on the integrated power comparator 1). Internally, i.e. on the integrated power comparator circuit 1, pin vboot is coupled to supply voltage Vddd via resistor R1 and diode D1.

During normal operation, the output 106 switches between power supply level Vdd and ground level Vss. If the output pin 106 is tied to ground (Vss), the capacitor Cboot is charged by the voltage source Vddd via R1 and diode D1. If the output pin 106 raises to Vdd, the voltage on vboot is raised to a voltage substantially higher than Vdd dependant on the charge on Cboot. If the capacitor Cboot has for example a value of 15 nF and the resistor R1 provides a resistance of 10 ohm, a “LOW” period (i.e. pin 106 at Vss) of about 500 nsec of output signal 106 is sufficient to charge the capacitor Cboot to a minimum value of 9 V.

However, it should be noted, that the high side driver 5 includes a charge guard protection circuit (not shown) for preventing operation when the voltage level across the boot capacitor Cboot drops below 9 V. On the other hand, the difference of the driver supply voltages of the high side driver and the low side driver 5, 6 should not be too large. If the driver voltage for the high side driver 5 is chosen too high, a shoot-through current can occur and destruct the output power stage 11. Further, before the self-oscillating class D system of FIG. 1 can start to operate, the bootstrap capacitor Cboot must be completely charged before the control logic 4 of the integrated power comparator 1 is enabled by the enable signal 105.

As the class D system shown in FIG. 1 needs proper start-up conditions on Cboot, in particular a sufficient voltage vboot, there are several circumstances under which the system may fail. For example, before the system is enabled by the mode input pin102, the output pin 106 is floating. In this situation, Cboot is charged to a value of Vddd−V_{D1}−Vdd/2, where V_{D1} is the voltage drop across diode D1. If Vdd and Vddd are assumed to be 12V and V_{D1} is 0.7V, the voltage across Cboot is only 5.3V. Accordingly, the voltage on Cboot is too low to activate the high side driver 5 and the transistor M2 will remain disabled by the charge guard protection. Under these circumstances, the system will not start oscillating. According to another example. it is assumed that the comparator 2 has a DC offset due to process parameter variations or the like and switches to HIGH, i.e. to Vdd when the mode input 102 is set active. As a consequence, the control logic 4 tries to activate high side driver 5, but without success, as Cboot is not sufficiently charged. Accordingly, the class D system of FIG. 1 will remain locked and not start oscillating.

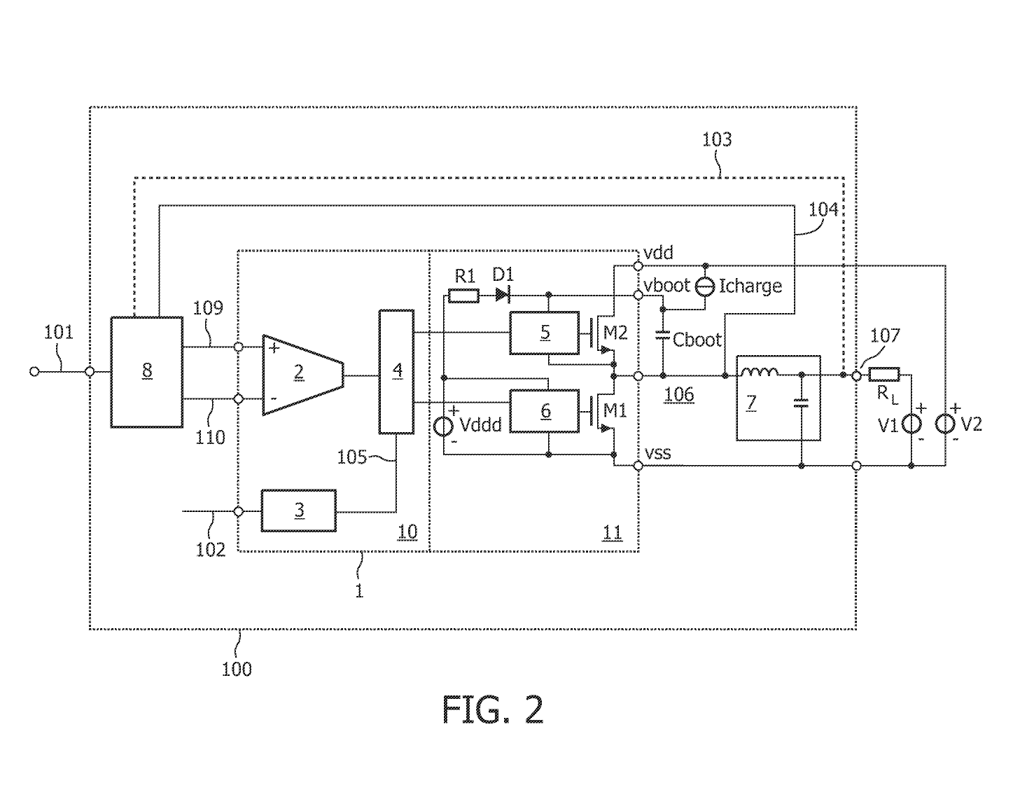

FIG. 2 shows a simplified schematic of a second embodiment of the prior art that is substantially similar to FIG. 1. However, in order to overcome the hang up problem during a start-up of the self-oscillating class D system shown in FIG. 1, this conventional solution suggests to include an additional current source I_{charge} between the first end of the boot capacitor Cboot, i.e. vboot, and Vdd. According to this principle, the boot capacitor Cboot is precharged by the current source I_{charge} before the output power stage 11 is switched on. This principle is only applicable to supply voltages having the following relation:

V2>2×(Vtr+Vcs)

wherein Vtr is the minimum voltage for the charge guard protection across Cboot to release the high side driver (e.g. 9 V) and Vcs is the voltage drop across the current source I_{charge} (e.g. 1 V). Accordingly, only if V2 is greater than 20 V, the current source I_{charge} for charging the boot capacitor Cboot may be successfully applied. However, most of the applications require a V2 of 12 V. Usually V1 corresponds to a voltage level V2/2. There is no specific problem, if V1 remains at 0 V during start-up, as the boot capacitor Cboot could be sufficiently charged during the first low cycle of the output signal. However, if the voltage level at node 107 is at V2/2 during start-up, the present principle will fail. The configuration shown in FIG. 2 will particulary fail, if after an error situation the system should be restarted within 100 msec. As the practical implementation of V1 is usually carried out by a simple electrolytic capacitor, is it almost impossible to charge and discharge the capacitor within 100 msec.

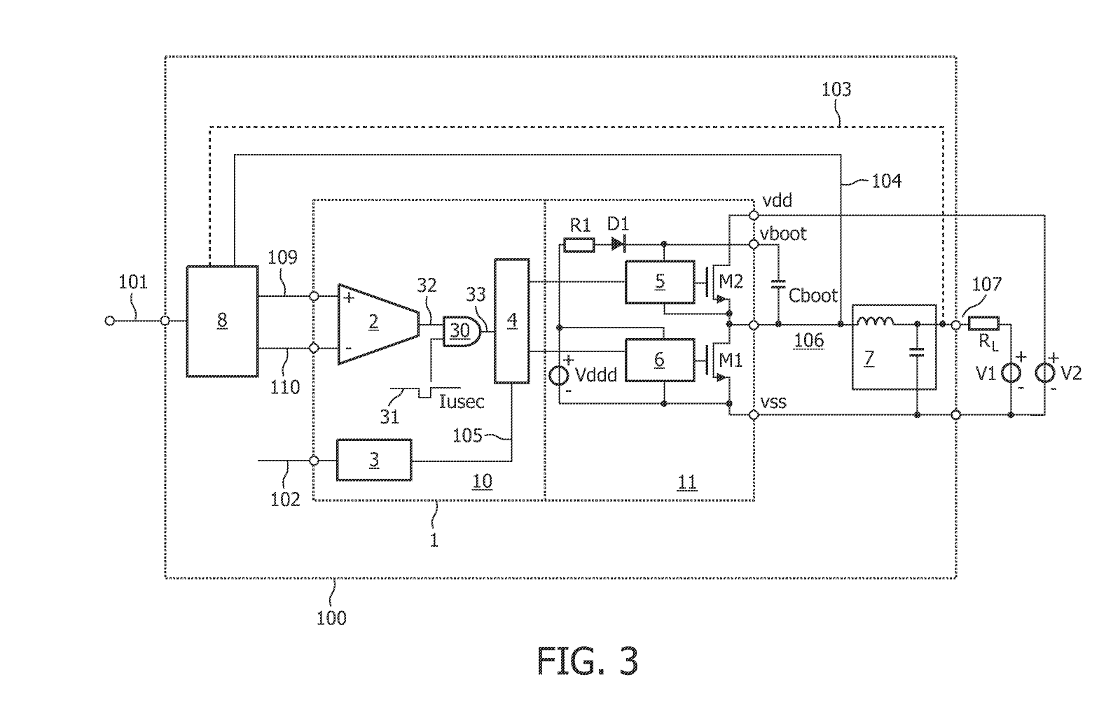

FIG. 3 shows another conventional circuit in order to prevent a hang up situation during the first switching cycles of the self-oscillating class D system described with respect to FIG. 1. Accordingly, the integrated power comparator 1 includes an additional AND gate 30 being coupled with a first input 32 to the output 33 of the comparator 2. The output of the AND gate 30 is coupled to the control logic 4. The second input 31 of the AND gate 30 receives an a short LOW pulse. According to this configuration, the signal 33 supplied to the control logic 4 is used to force the output pin 106 of the output power stage 11 to Vss. The problem of this approach, is that the LOW period must be correlated with the oscillating frequency of the class D system. Otherwise, the LOW pulse causes negative audible effects. As the oscillating frequency is variable, and usually externally adjusted by the discrete loop filter 8, whereas the pulse is predetermined in the integrated power comparator 1, the required correlation will usually be not established.

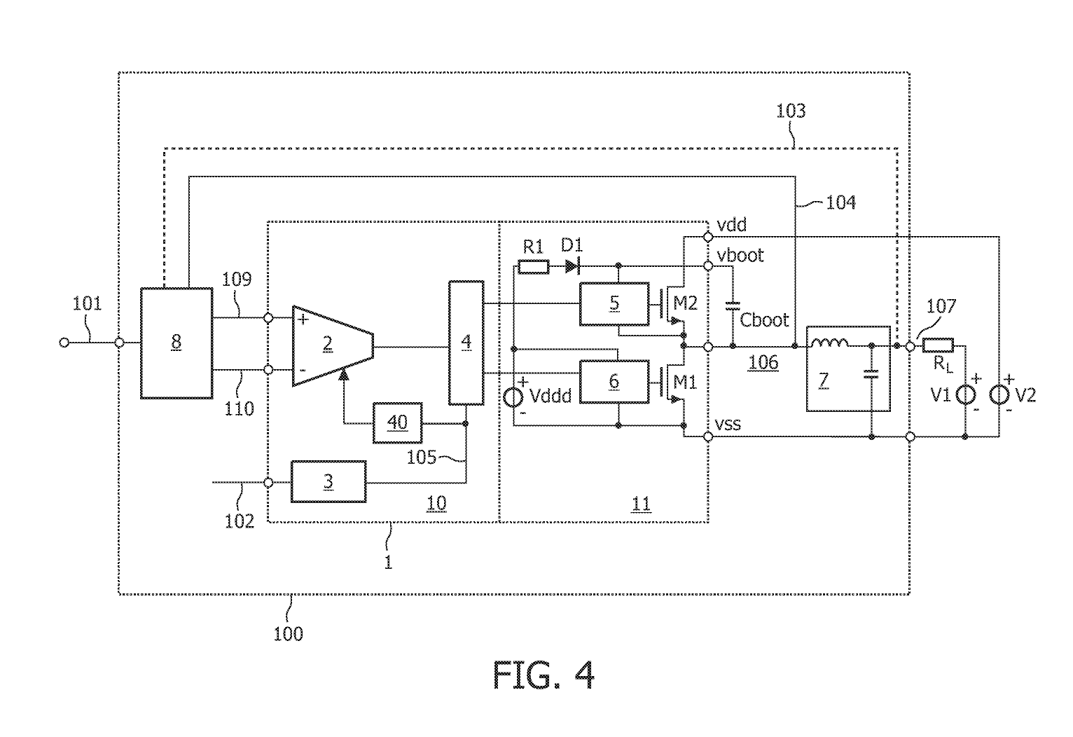

FIG. 4 shows a simplified block diagram of a self-oscillating class D system according to an embodiment of the present invention. Accordingly, a compensation circuit 40 is provided between the enable signal 105 and the comparator 2. The compensation circuit 40 provides a compensation signal 401 to the comparator 2. The compensation signal compensates a deficiency of the comparator that is caused by production spread, such as process parameter variations of the integrated power comparator 1 during manufacturing. A typical deficiency to be compensated by the compensation signal 401 is an offset of the comparator 2, as described above. The compensation circuit 40 can provide a single shot, i.e. a short pulse signal to the comparator 2 during start up. Accordingly, a small unbalance is introduced in the comparator such that the comparator output is set to LOW. If the comparator output is set to LOW, the control logic 4 sets the output signal 106 of the power output stage 11 also to Vss. Accordingly, the bootstrap capacitor Cboot is charged by the voltage source Vddd via resistor R1 and diode D1. The compensation signal that is fed to the comparator 2 is typically derived from a one-shot circuit with a time constant of 1 μsec. The compensation signal 401 is such that it compensates the offset of the comparator just sufficiently to pull the output of the comparator to LOW. The introduced offset by compensation signal 401 is dimensioned based on the maximum DC-offset of the comparator 2 caused by process variations. This way, only the uncertainty that the first switching cycle will not be to the low side is reduced to zero. The natural frequency of the oscillating loop is not affected. Already during the first cycles, the self-oscillating class D system starts oscillating at its own frequency, without audible disturbances, like the typical plop sound of conventional systems.

The dashed boxes in FIGS. 1 to 4 for the integrated power comparator 1 and the class D system 100 indicate optional suggestions for an implementation, as for example a single integrated circuit for the integrated power comparator 1 or the like. However, the shown boxes are mere suggestions and they do not represent any limitation to the possible implementations of the circuits according to the present invention as integrated circuits or as discrete components on printed circuit boards.

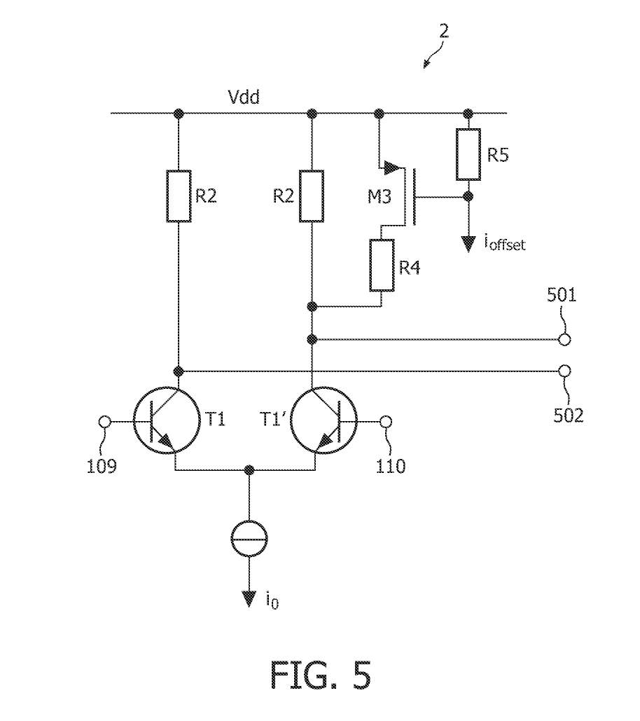

FIG. 5 shows in more detail how the compensation signal 401 can compensate the offset of a comparator 2 according to an aspect of the present invention. The differential stage of the comparator 2 includes transistors T1 and T1′. The input signals 109 and 110 are applied to the respective negative and positive input pins of transistors T1, T1′. The differential pair T1, T1′ is biased by a current source i₀. Resistors R2 and R2′ represent the respective loads for transistors T1, T1′. The output signals 501, 502 of comparator 2 are coupled directly or via additional components (usually logic gates, not shown) to control logic 4 (shown in FIG. 4) or a similar circuit. Transistor M3, and the resistors R4, and R5 are provided to introduce a current i_{offset} in the branch including R2′ and T1′. If a current i_{offset} is drawn via R5, a corresponding current (maybe of different size due to transistor dimensions) through M3 and R4 is provided being fed to the right half of the differential pair T1, T1′. This additional current will cause an unbalance in the two branches of the comparator that can prompt the comparator 2 to switch to another output state, e.g. from HIGH to LOW or vice versa. Dependent on the predicted maximum offset of the comparator, the current i_{offset} is dimensioned to compensate, i.e. to slightly over-compensate the offset. The size of the current can be dimensioned in relation to the maximum DC offset that usually occurs due to process parameter variations during production of the integrated power comparator. Accordingly, the comparator and thereby the output signals 501, 502 are switched as a current i_{offset} is drawn through R5. According to an aspect of the present invention, the current i_{offset} is typically only applied during a short period of 1 μsec or the like. The period of the pulse of 1 μs is chosen to be shorter than the period of the self-oscillating class D system. If for example, the class D system is designed to oscillate at a frequency of 500 kHz, the period of the class D system is 2 μs. If the oscillating frequency varies, the pulse duration may be modified suitably.

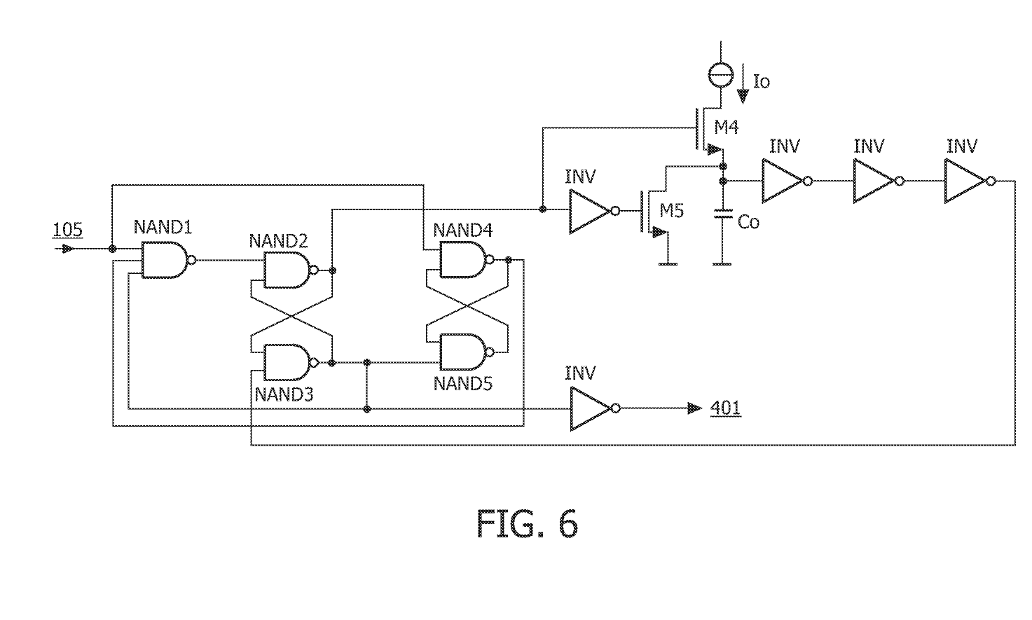

FIG. 6 shows a simplified schematic of a one-shot circuit according to the present invention. The circuit shown in FIG. 6 provides a short pulse of an approximately 1 μsec for the compensation principle according to an aspect of the present invention. In the steady state condition the enable signal 105 is LOW and the output signal 401 is also LOW. In order to issue a single shot, enable signal 105 is assumed to change from LOW to HIGH. Accordingly, the output of NAND1 changes from HIGH to LOW. The time during which NAND1 is LOW is determined by the propagation delay of the gates, in particular the three inverters INV coupled to the source of M4. NAND2 and NAND3 constitute a flip-flop that is set by the negative edge of the output signal of NAND1. In response the negative edge of the output of NAND1, NAND2 goes HIGH. As the output of NAND2 is coupled to M5 via an inverter INV, M5 is turned off. Simultaneously, M4 is switched on, and the current Iₒ starts charging Co. While Co is charged, output 401 is HIGH, since NAND3 is LOW. The charging of capacitor Co is dimensioned to take about 1 μsec. When the voltage at the capacitor Co crosses the threshold level of the inverter INV, the output of the chain of inverters INV switches to low and the flip-flop consisting of NAND2 and NAND3 is reset, such that output 401 goes LOW. Accordingly, NAND2 goes LOW. M4 is turned off and M5 is turned on, thereby discharging Co. This ensures a single pulse of a duration of 1 μsec on output 401.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single electronic component or other unit recited in the claims may be replaced by several items and vice versa. The mere fact that certain measures are recited in mutually different dependent claims does not indicate that a combination of these measures cannot be used to advantage. Any reference signs in the claims should not be construed as limiting the scope.

1. Electronic device comprising:
an integrated power comparator circuit for a self-oscillating class D system (100), the integrated power comparator circuit comprising:
a modulation stage,
the modulation stage comprising:
compensation circuit for providing a compensation signal to the modulation stage, the compensation signal being dimensioned for compensating an effect of a variation of a production parameter for smoothing initialization of the self-oscillating class D system.

2. Electronic device according to claim 1, wherein the modulation stage comprises a comparator, and the offset compensation circuit is adapted to provide an offset compensation signal for compensating an offset of the comparator being the effect of the variation of the production parameter.

3. Electronic device according to claim 2, wherein the compensation signal introduces a unbalance into the comparator for compensating the offset of the comparator by introducing an additional current into an electrical path of the input stage of the comparator.

4. Electronic device according to claim 1, wherein the compensation signal provides a pulse and the variation of the process parameter is compensated for the duration of the pulse.

5. Electronic device according to claim 4, wherein the duration of the pulse of the compensation signal is substantially shorter than the period of the natural oscillating frequency of the class D system.

6. Electronic device according to claim 1, wherein the integrated power comparator circuit comprises further a power output stage, wherein the power output stage comprises:
a first NMOS transistor and a second NMOS transistor,
a first low side driver for driving the first NMOS transistor, and a second high side driver for driving the second NMOS transistor,
the output of the comparator being coupled to the first low side driver and the second high side driver.

7. Method of designing an electronic device comprising the steps of:
providing a compensation circuit for a modulation stage of an integrated power comparator circuit for a self-oscillating class D system,
the compensation circuit being adapted to provide a compensation signal to the modulation stage, the compensation signal being dimensioned for compensating an effect of a variation of a production parameter for smoothing initialization of the self-oscillating class D system.

8. Method of operating a class D system comprising the steps of:
providing a compensation signal to a modulation stage for an integrated power comparator circuit for a self-oscillating class D system, the compensation signal being dimensioned for compensating an effect of a variation of a production parameter for smoothing initialization of the self-oscillating class D system.

9. The method according to claim 8, wherein the modulation stage comprises a comparator, and the offset compensation signal provides a pulse for over-compensating an offset of the comparator being the effect of the variation of the production parameter.
